(19) United States
(12) Patent Application Publication
(10) Pub. No.: US 2025/0048556 A1
(43) Pub. Date: Feb. 6, 2025

(54) Metal-ceramic substrate and method for producing a metal ceramic substrate

(71) Applicant: Rogers Germany GmbH, Eschenbach (DE)

(72) Inventor: Andreas Meyer, Speichersdorf (DE)

(21) Appl. No.: 18/697,158

(22) PCT Filed: Sep. 30, 2022
(86) PCT No.: PCT/EP2022/077292

§ 371 Date: Mar. 29, 2024

(30) Foreign Application Priority Data
Oct. 1, 2021 (DE) 10 2021 125 557.0

(51) Int. Cl. H05K 1/18; H05K 1/03; H05K 3/06

(52) U.S. Cl. CPC H05K 1/181; H05K 1/0306; H05K 3/06; H05K 2201/0338; H05K 2201/09227

(57) ABSTRACT

A metal-ceramic substrate (1) provided as a printed circuit board for attaching electrical components, comprising
a component metallization (10) and a backside metallization (20), and
a ceramic element (30) arranged along a stacking direction (S) between the component metallization (10) and the backside metallization (20),
wherein the component metallization (10) comprises a first metal section (11) and a second metal section (12), the first metal section (11) and the second metal section (12) being separated from each other by an isolation section (15), and
wherein the backside metallization (20) has a material weakening (25), in particular a material recess, which is arranged to be congruent with the isolation section (15) when viewed in the stacking direction (S).

### CROSS REFERENCE TO RELATED APPLICATIONS

This application is a National Stage application of PCT/EP2022/077292, filed Sep. 30, 2022, which claims the benefit of German Patent Application No. 10 2021 125 557.0, filed Oct. 1, 2021, both of which are incorporated by reference in their entirety herein.

### BACKGROUND

The present invention relates to a metal-ceramic substrate and a method of manufacturing a metal-ceramic substrate.

Carrier substrates for electrical components, for example in the form of metal-ceramic substrates, are sufficiently known from the prior art, for example as printed circuit boards or circuit boards, for example from DE 10 2013 104 739 A1, DE 19 927 046 B4 and DE 10 2009 033 029 A1. Typically, connecting areas for electrical components and conductor paths are arranged on one component side of the metal-ceramic substrate, wherein the electrical components and conductor paths can be interconnected to form electrical circuits. Essential components of the metal-ceramic substrates are an insulating layer, which is preferably made of ceramics, and a component metallization or component metallization bonded to the insulating layer. Due to their comparatively high insulation strength, insulating layers made of ceramics have proven to be particularly advantageous in power electronics. By structuring the component metallization, conductor paths and/or connecting areas for the electrical components can then be created.

A high-temperature process such as hot isostatic pressing, a diffusion bonding process, a direct metal bonding process, a DCB process or an active soldering process is usually provided for bonding component metallization to the ceramic element. To form individual conductor paths or connecting areas, the bonded component metallization is structured in such a way that at least a first metal section and a second metal section are formed in the component metallization, which are separated and isolated from each other. Since the component metallization and the ceramic element have different expansion coefficients, thermomechanical stresses develop in the bonding interface between the component metallization and the ceramic element when temperatures develop, for example during bonding or due to electrical components, which can cause the entire metal-ceramic substrate to deflect. To counteract this effect, the prior art provides for a backside metallization to be bonded to the ceramic element in order to create symmetry between the component side and the backside of the metal-ceramic substrate.

Based on the prior art, the present invention has the object of improving metal-ceramic substrates in such a way that their susceptibility to deflection is further reduced and metal-ceramic substrates which are as flat as possible are provided.

### SUMMARY

The present invention achieves this object with a method as described herein and a metal-ceramic substrate manufactured with a method as described herein.

According to a first aspect, a metal-ceramic substrate is provided which is provided or intended as a printed circuit board for attaching electrical components, comprising:
a component metallization and a backside metallization, and
a ceramic element arranged along a stacking direction between the component metallization and the backside metallization,
wherein the component metallization comprises a first metal section and a second metal section, the first metal section and the second metal section being separated from each other by an isolation section, and
wherein the backside metallization has a material weakening, in particular a material recess, which is arranged congruent with the isolation section when viewed in the stacking direction.

### BRIEF DESCRIPTION OF THE DRAWINGS

Further advantages and features result from the following description of preferred embodiments of the object according to the invention with reference to the attached figures. Individual features of the individual embodiments can be combined with one another within the scope of the invention.

### It is Shown:

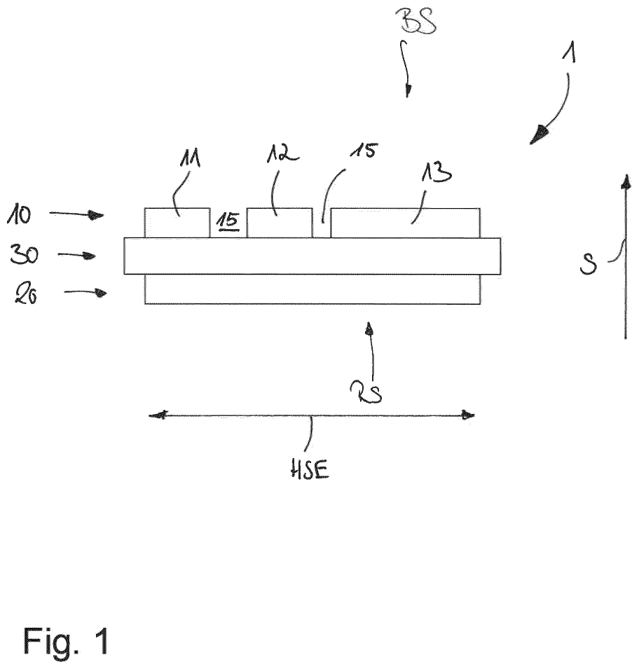

FIG. 1: a metal-ceramic substrate according to the prior art,

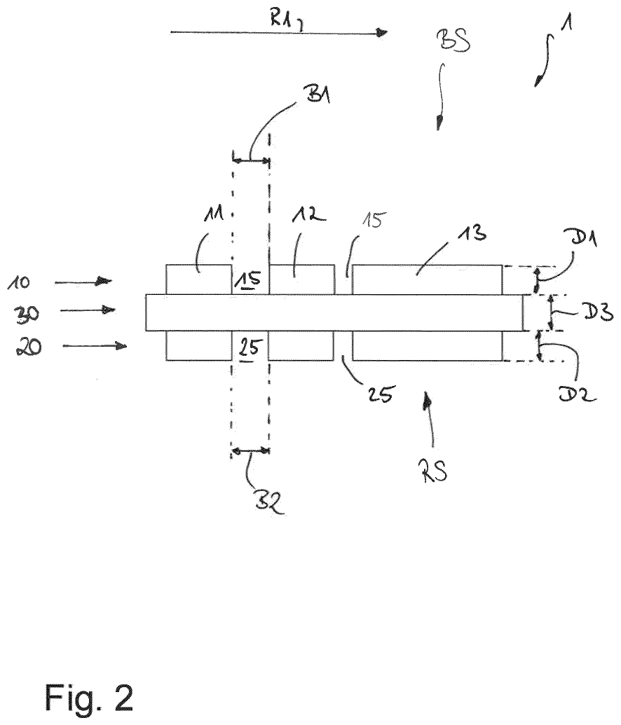

FIG. 2: a metal-ceramic substrate according to a first exemplary embodiment of the present invention in a sectional view

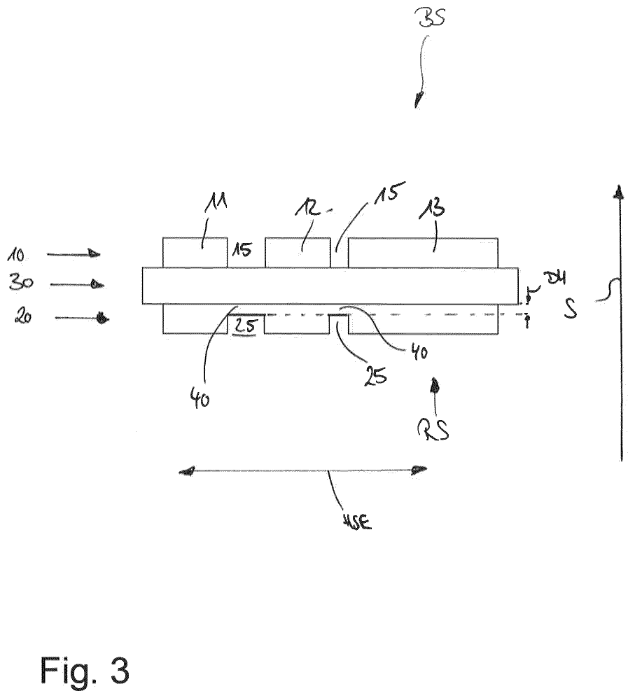

FIG. 3 a metal-ceramic substrate according to a second exemplary embodiment of the present invention in a sectional view

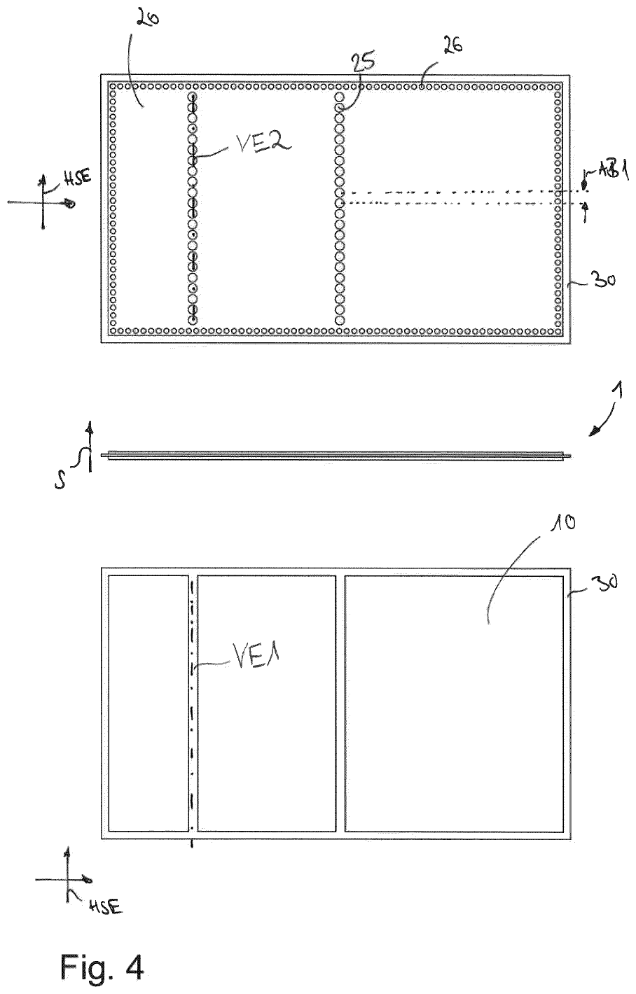

FIG. 4 metal-ceramic substrate according to a third exemplary embodiment of the present invention,

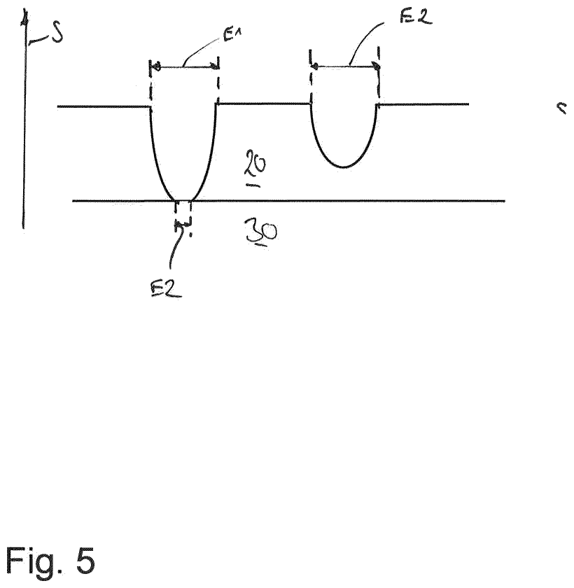

FIG. 5 two different material weakenings for the backside metallization

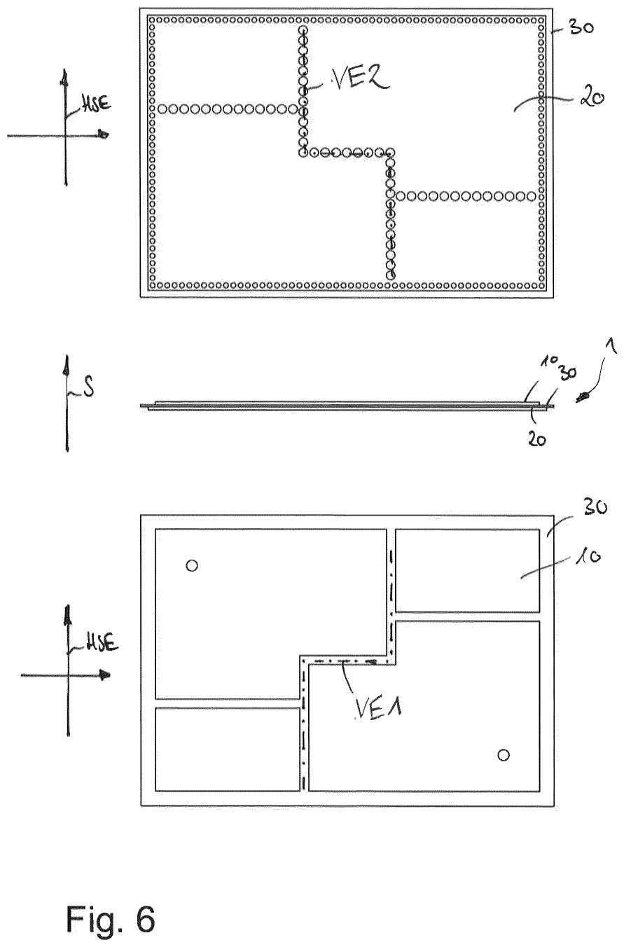

FIG. 6 a component metallization (bottom) and a backside metallization (top) and a side view (middle) of a metal-ceramic substrate according to a fourth embodiment of the present invention and

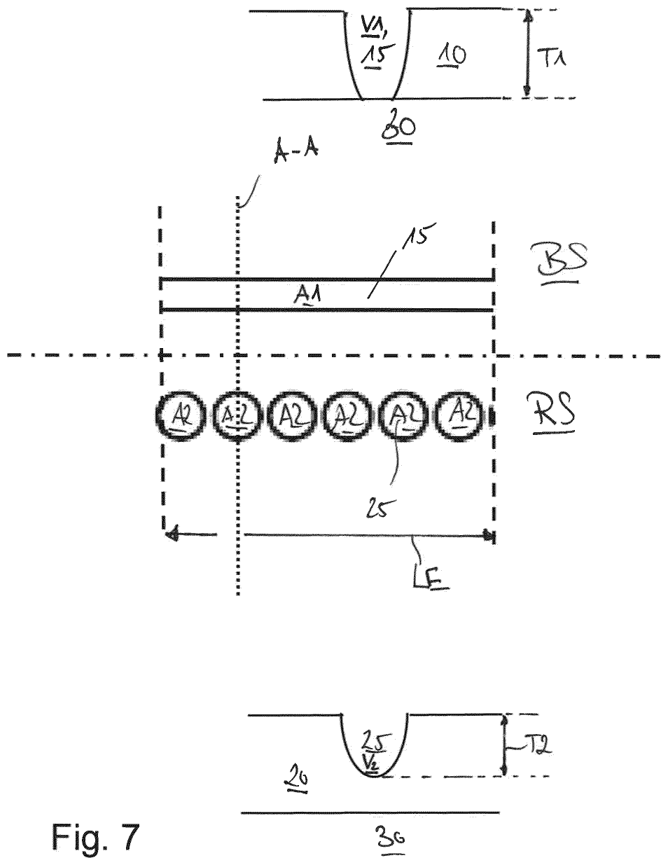

FIG. 7 a comparison between a recess forming the isolation section and a recess forming a material weakening for a metal-ceramic substrate according to a fifth exemplary embodiment of the present invention.

### DETAILED DESCRIPTION

In contrast to the metal-ceramic substrates known from the prior art, it is provided that the backside metallization has material weakenings which are arranged precisely such that they are arranged or extend congruent with the isolation section or sections on the component side. This advantageously increases the symmetry of the material distribution on the component side and the opposite backside. As a result, the susceptibility to bending of the overall substrate can be reduced, as the thermomechanical stresses occurring on the component side and the backside compensate each other. This means that the tendency to bend can be further reduced and metal-ceramic substrates that are as flat as possible can be provided. For this purpose, it is preferably provided that a first thickness of the component metallization essentially corresponds to a second thickness of the backside metallization.

A congruent arrangement means in particular that in the case of the imaginary projection of the material weakening along the stacking direction or along a direction running parallel to the stacking direction, a spatial overlap with the isolation section would be established. In this case, this imaginary spatial overlap occurs for more than 50%, more preferably more than 75% and most preferably for more than 90% of the extension of the material weakening in the backside metallization. The center of the extension of the material weakening can be arranged essentially congruent with the center of the extension of the isolation section or offset laterally, i.e. along a direction perpendicular to the stacking direction.

Furthermore, it is preferably provided that the ceramic element has a third thickness measured along the stacking direction. It is particularly preferably provided that the third thickness is less than 700 μm, more preferably less than 400 μm and most preferably less than 330 μm. The symmetry between the material weakenings in the backside metallization and the isolation sections in the component metallization proves to be particularly advantageous for comparatively thin insulating layers or ceramic elements, because these ceramic elements are particularly susceptible to bending and even breaking. For example, it is even conceivable that the third thickness of the ceramic element is smaller or thinner than the first thickness of the component metallization and the second thickness of the backside metallization or the sum of the first thickness and the second thickness.

Furthermore, it is preferably provided that the structuring and/or the letting in of the material weakening is performed after the bonding of the metallization and/or backside metallization to the ceramic element.

In particular, it is a metal-ceramic substrate that is used as a printed circuit board, in which a metallization, i.e. a component metallization, is formed on the component side, which has several electrically insulated metallization sections due to the structuring. These metallization sections form, for example, connecting areas or pads or conductor paths of the printed circuit board.

Preferably, the ceramic element has Al₂O₃, Si₃N₄, AlN, an HPSX ceramic (i.e. a ceramic with an Al₂O₃ matrix comprising an x-percentage of ZrO₂, for example Al₂O₃ with 9% ZrO₂=HPS9 or Al₂O₃ with 25% ZrO₂=HPS25), SiC, BeO, MgO, high-density MgO (>90% of the theoretical density), TSZ (tetragonally stabilized zirconium oxide) as the material for the ceramic. It is also conceivable that the ceramic element is formed as a compound or hybrid ceramics in which several ceramic layers, each of which differs in terms of its material composition, are arranged on top of one another and joined together to form an insulating element in order to combine various desired properties.

Copper, aluminium, molybdenum, tungsten and/or their alloys, such as CuZr, AlSi or AlMgSi, as well as laminates such as CuW, CuMo, CuAl and/or AlCu or MMC (metal matrix composite), such as CuW, CuMo or AlSiC, are conceivable as materials for the component metallization and/or backside metallization. Preferably, the component metallization corresponds to or differs from the backside metallization in terms of its material. Furthermore, it is preferably provided that the component metallization and/or the backside metallization on the manufactured metal-ceramic substrate is surface-modified, in particular as component metallization. Surface modification could be, for example, sealing with a noble metal, in particular silver and/or gold, or (electroless) nickel or ENIG (“electroless nickel immersion gold”) or edge encapsulation on the metallization to suppress crack formation or expansion. For example, the metal of the component metallization also differs from the metal of the backside metallization.

The bonding of the metal layer, i.e. the component metallization and/or the backside metallization, to the ceramic element can be carried out, for example, via a DCB method, an AMB method, diffusion bonding, in particular ADB, and/or hot isostatic pressing.

The skilled person understands a “DCB method” (direct copper bonding technology) or a “DAB method” (direct aluminum bonding technology) to be such a method which is used, for example, for joining metal layers or sheets (e.g. copper sheets or foils or aluminum sheets or foils) to each other and/or to ceramic or ceramic layers, namely with the use of metal sheets or copper sheets or metal foils or copper foils which have a layer or coating (melting layer) on their surface sides. In this method, described for example in U.S. Pat. No. 3,744,120 A or DE23 19 854 C2, this layer or coating (melting layer) forms a eutectic with a melting temperature below the smelting temperature of the metal (e.g. copper), so that by placing the foil on the ceramic and heating all the layers, they can be joined to one another by smelting the metal or copper essentially only in the area of the melting layer or oxide layer.

Preferably, the ceramic layer and the metal layer are joined by means of a direct metal bonding process, a hot isostatic pressing process, a soldering process and/or a diffusion bonding process.

In particular, the DCB method then has the following method steps, for example:
Oxidizing a copper foil in such a way that a uniform copper oxide layer is formed;
Placing the copper foil on the ceramic layer;
Heating the compound to a processing temperature between approx. 1025 and 1083° C., e.g. to approx. 1071° C.;
Cooling to room temperature.

An active solder process, e.g. for joining metal layers or metal foils, in particular also copper layers or copper foils with ceramic material, is to be understood as a method which is also used specifically for the production of metal-ceramic substrates, is manufactured at a temperature between approx. 600-1000° C. between a metal foil, for example copper foil, and a ceramic substrate, for example aluminum nitride ceramic, with the use of a hard solder which also contains an active metal in addition to a main component such as copper, silver and/or gold. This active metal, which is for example at least one element from the group Hf, Ti, Zr, Nb, Ce, creates a bond between the solder and the ceramic by chemical reaction, while the bond between the solder and the metal is a metallic brazing joint. Alternatively, a thick-film process is also conceivable for bonding.

Preferably, an ADB (active diffusion bonding) method is provided as the diffusion bonding method, which comprises the following steps, for example:
Providing a ceramic element and a metal layer,
providing a gas-tight container which encloses the ceramic element, wherein the container is preferably formed from the metal layer or comprises the metal layer,
forming the metal-ceramic substrate by bonding the metal layer to the ceramic element by hot isostatic pressing,
   wherein an active metal layer or a contact layer comprising an active metal is arranged at least in sections between the metal layer and the ceramic element to support the bonding of the metal layer to the ceramic element in order to form the metal-ceramic substrate. The container is preferably formed as a metal container from a metal layer and/or a further metal layer. Alternatively, it is also conceivable that a glass container is used.

In hot isostatic pressing, bonding is provided in particular by heating under pressure, in which the metal layer of the metal container, in particular the subsequent metal layer of the metal-ceramic substrate and any eutectic layer occurring there, does not pass into the melting phase. Accordingly, lower temperatures are required for hot isostatic pressing than for a direct metal bonding method, in particular a DCB method.

Compared to the bonding of a metal layer to a ceramic layer by means of a solder material, in which temperatures below the melting temperature of the at least one metal layer are usually used, the present procedure advantageously dispenses with a solder base material and only an active metal is required. The use or utilization of pressure during hot isostatic pressing also proves to be advantageous because air inclusions or cavities between the metal layer on the one hand and the ceramic element on the other can be reduced, thus reducing or even avoiding the forming of voids in their frequency in the formed or manufactured metal-ceramic substrate. This has an advantageous effect on the quality of the bond between the metal layer of the metal container and the ceramic element. In addition, it is advantageously possible to simplify the “second etching” and avoid solder residues and silver migration.

The contact layer comprising the active metal layer comprises active metal of more than 15 weight percent.

Hot isostatic pressing is known, for example, from EP 3 080 055 B1, to the contents of which explicit reference is hereby made with regard to hot isostatic pressing.

Furthermore, the material weakening is more preferably formed as a dome-shaped recess. It is conceivable that one opening of these dome-shaped recesses in the backside metallization faces the ceramic element and/or faces away from it. As a material weakening, it would also be conceivable that a material section is provided in the backside metallization whose material differs from that from which the backside metallization is made. For example, the respective recesses in the backside metallization could be filled with corresponding filling materials whose expansion coefficients do not contribute significantly to forming or supporting/reinforcing thermomechanical stresses. Such filling materials increase stability without jeopardizing the desired thermomechanical symmetry between the component side and the backside.

The recesses can also have a circular, diamond-shaped, square, rectangular or polygonal cross-section in a direction parallel to the main extension plane. In particular, it should be noted that the congruent arrangement relates to the arrangement of the material weakening. In contrast, it is not necessary, for example, for a backside material weakening to be provided for each subregion of the component-side isolation section. In other words, a first total area occupied by the isolation sections in the component metallization is larger than a second total area occupied by the material weakenings in the backside metallization. It is preferably provided that a ratio of the second area to the first area has a value of between 0.6 and 0.9, more preferably between 0.7 and 0.9 and most preferably between 0.75 and 0.9. Here, further material weakening is more preferably not taken into account, which is realized in addition to the material weakenings that are embedded in the backside metallization congruently with the isolation sections.

In particular, it is conceivable that the isolation section in the component metallization extends along a first course, in particular extends uninterruptedly, while on the opposite side in a congruent arrangement in the backside metallization a plurality of material weakenings separated from one another is formed. Furthermore, it is provided that the material weakening on an outer side of the backside metallization, which faces away from the ceramic element, has a first extension which is smaller than 1.0 mm, more preferably smaller than 0.8 mm and most preferably smaller than 0.7 mm. Furthermore, it is preferably provided that two adjacent material weakenings are arranged at a first distance from one another which is less than 600 μm, more preferably less than 400 μm and most preferably less than 250 μm. Furthermore, it is conceivable that the first distance and/or the first extension may differ for several material weakenings. Alternatively, it is conceivable that, for example, the first extension or the first distance between two adjacent material weakenings in the backside metallization is the same.

Preferably, it is provided that the isolation section in the component metallization follows a first course in a plane running parallel to the main extension plane and one or more material weakenings in the backside metallization follow a second course in a plane extending parallel to the main extension plane, wherein in the stacking direction the second course is arranged congruently with the first course, in particular the second course is more than 50% of its total extension, more preferably more than 70% and most preferably more than 90% or completely congruent with the first course. Thus, the material weakenings and the isolation section are not only arranged congruently to one another in a cross-section that runs perpendicular to the main extension plane, but also with regard to their first and second courses, along which the isolation sections and material weakenings extend in a plane running parallel to the main extension plane. It is conceivable that singulated sections or partial sections in the backside metallization are omitted with respect to their congruent arrangement to the isolation section or isolation sections. In other words: In so far as there is a material weakening in the backside metallization, this is preferably always arranged congruently with an isolation section, while material weakening in the backside metallization is not necessarily required for the isolation section to be congruent with the isolation section. If necessary, this can prevent the backside metallization in this metal area from being weakened too much due to closely spaced isolation sections.

The first course and/or the second course can have straight or curved sections that are arranged at an angle or offset to one another. Furthermore, it is more preferably provided that the second course of the material weakening or the material weakenings is formed by a series of material weakenings, for example in the form of a row of holes or a series of dome-shaped recesses, and/or that along the second course the backside metallization has a stabilization region between two material weakenings. In particular, a row of holes is formed by a series of adjacent dome-shaped recesses. It is conceivable that a partial section is formed between two adjacent dome-shaped recesses in which the backside metallization has the second thickness or a residual metallization is provided that is greater than the residual metallization between the recess and the ceramic element. As a result, the stability of the metal-ceramic substrate is maintained despite the increase in symmetry. It is preferably provided that a first distance between two adjacent material weakenings is less than 600 μm, less than 400 μm and most preferably less than 250 μm. In particular, it is provided that the recesses are manufactured by a chemical method, for example etching, by a mechanical method, for example milling, or by an optical method, for example by means of laser light, in particular laser pulses. The use of laser light in particular allows the narrowest and most precisely positioned forming of material weakenings, especially recesses. The stabilization region is preferably characterized by the fact that the material weakening is less pronounced. For example, the depth of a recess in the stabilization region is smaller or, in some areas, there is no recess at all in the stabilization region.

Preferably, in addition to the material weakening, which is arranged congruently with the isolation sections, a further material weakening is provided, which is embedded in the backside metallization in a peripheral region of the backside metallization. In contrast to the material weakening, it is provided for the further material weakening that, viewed in the stacking direction, no congruently arranged isolation sections are provided or formed on the opposite side.

For example, it is preferably provided that the further material weakening is arranged in such a peripheral region of the backside metallization which protrudes from the component metallization in a direction parallel to the main extension plane. In this case, the component metallization is smaller than the backside metallization, in particular with regard to its extension along the main extension plane.

The further material weakenings can form a row of holes or be formed as a flat side surface, i.e. in particular with a comparatively small angle of inclination, which is, for example, at least a factor of 2, more preferably at least a factor of 3 and most preferably at least a factor of 5 smaller than a corresponding angle of inclination on the component side. The different extensions of the component metallization and backside metallization ensure a sufficient distance from the outer edge of the ceramic element on the component side to prevent electrical flashover, while the section of the backside metallization that protrudes from the component metallization increases the stability of the metal-ceramic substrate in the peripheral region.

It has been found that this measure of further material weakening can achieve an additional improvement in the metal-ceramic substrate, which can counteract the susceptibility of the metal-ceramic substrate to bending and, in particular, further increase the thermal shock resistance. The further edge-side material weakening can also be designed as a curved sidewall profile with at least one intermediate maximum. Furthermore, it is preferably provided that a first extension of the further material weakening is smaller than the first extension of the material weakening. If the material weakening and the further material weakening each have different extensions, it is preferably provided that the respective mean value is taken into account. Furthermore, it is provided that the peripheral region is to be understood as the partial section of the metallization or backside metallization which extends from the outer circumference of the backside metallization and in so doing occupies less than 10%, more preferably less than 5% and most preferably less than 2% of the total area of the backside metallization. Furthermore, it is provided that the furthe material weakening surrounds, in particular completely frames, the area with the material weakenings.

Furthermore, it is more preferably provided that a material weakening in the form of a recess runs up to the ceramic element or extends to the ceramic element. This achieves a high degree of symmetry between the component side and the backside. Alternatively, it is conceivable that a residual metallization is formed in the area of the material weakening, so that this residual metallization can contribute to increasing the stability of the entire metal-ceramic substrate. This is particularly advantageous when using very thin insulating layers or ceramic elements, which would otherwise have an increased tendency to break. For example, it is provided that, measured in the stacking direction, the residual metallization has a fourth thickness, wherein a ratio of the fourth thickness to the second thickness is less than 0.5, more preferably less than 0.4 and most preferably less than 0.2.

It is also conceivable that a residual metallization is formed between the further material weakening formed as a recess and the ceramic element, in particular if the material weakening formed as a recess extends as far as the ceramic element. This distinguishes the material weakening from the further material weakening in the peripheral region, for example.

Preferably, it is provided that a first width of the isolation section is determined by a distance between the first metal section and the second metal section, measured along a first direction which runs perpendicular to the first course, wherein a ratio of a second width of the material weakening, measured along the first direction, to the first width has a value between 0.1 and 2, more preferably between 0.5 and 1.5 and most preferably between 0.75 and 0.9. In particular, it has been shown that a sufficient degree of symmetry with regard to the thermodynamic extension on the component side and backside can already be set if the material weakening on the backside metallization does not extend across the full second width of the isolation section. As a result, the stability of the metal-ceramic substrate can be maintained without having to fear that a possible fracture point for the metal-ceramic substrate will occur due to the small amount of material on the backside.

Preferably, it is provided that a ratio of sections in which the first course and the second course do not run congruently with one another as seen in the stacking direction to sections in which the first course and the second course run congruently with one another as seen in the stacking direction has a value which is less than 1, more preferably less than 0.5 and most preferably less than 0.2. It has been found that the overall symmetry at the front and back of the metal-ceramic component can be increased with an increasing proportion of congruently arranged material weakenings, thus further improving or reducing the overall tendency to bend for the correspondingly designed metal-ceramic substrates.

Preferably, it is provided that a heat sink is bonded to the backside metallization. In particular, it is provided that the material weakening is embedded in the backside metallization, for example in the form of the recess. Thus, the material weakening embedded in the backside metallization is not a recess that is embedded in the heat sink, which is bonded to the backside metallization and is provided in particular to dissipate the heat generated during operation of the specific metal-ceramic substrate to a cooling fluid.

In particular, it is provided that per unit of length along the first course and/or the second course, the isolation section has a first volume and the material weakening in the backside metallization has a second volume, wherein the first volume and the second volume are substantially equal with respect to their absolute size and are different with respect to their geometric shapes. In this way, on the one hand, the symmetry between the recesses in the component metallization and the recesses in the backside metallization can be kept as large as possible and, at the same time, measures can be taken to strengthen the stability in the areas in which the isolation section or the material weakening is embedded. In this context, the skilled person preferably understands “substantially equal” volumes to be those that do not deviate from each other by more than 10%, more preferably not more than 5% and most preferably not more than 2.5% of their mean value. The first volume and the second volume can differ, for example, in terms of their depth, their width and/or their length. Accordingly, correspondingly different widths or diameters can be used, for example, for recesses of different depths on the component side and the backside, in order to ensure that the volumes of the recesses in the component metallization and the backside metallization essentially match.

According to another object of the present invention, a metal-ceramic substrate provided as a printed circuit board for attaching electrical components is provided, comprising:
a component metallization and a backside metallization, and
a ceramic element arranged along a stacking direction between the component metallization and the backside metallization,
   wherein the component metallization comprises a first metal section and a second metal section, wherein the first metal section and the second metal section are separated from each other by an isolation section and/or a connection region for an electrical component is provided on the first metal section, and
   wherein the backside metallization has a material weakening, in particular a material recess, which, viewed in the stacking direction, is arranged to be at least partially congruent with the connection region. All the advantages and properties described for the metal-ceramic substrate with the material weakenings arranged congruently with the isolation sections can be transferred analogously to the advantages and properties or specifications described for the metal-ceramic substrates with the material weakenings congruent with the connection regions and vice versa. In particular, a metal-ceramic substrate is conceivable that has both material recesses that are congruent with the isolation sections and (further) material recesses that are congruent with the connection region.

Preferably, the connection region is characterized by a corresponding planar extension, which is obviously different from conductor paths because they are wider in a main extension plane than conductor paths. It is conceivable that the material weakening extends across the entire area arranged congruently below the connection region. It is also conceivable that the partial section of the backside metallization that is congruent with the connection region only has material weakening in some areas, for example congruent with an edge section of the connection region. Preferably, the material weakenings, which are arranged congruently below the connection region, are arranged in a two-dimensional pattern.

A further object of the present invention is a method of manufacturing a metal-ceramic substrate, in particular of manufacturing a metal-ceramic substrate according to the invention, comprising:
Providing a component metallization and a backside metallization, and a ceramic element,
bonding the component metallization and the backside metallization to the ceramic element, wherein the ceramic element is arranged along a stacking direction between the component metallization and the backside metallization,
structuring the component metallization by realizing isolation sections and
realizing a material weakening in the backside metallization, wherein the material weakening is arranged congruently with the isolation section as viewed in the stacking direction.

All the advantages and properties or specifications described for the metal-ceramic substrate can be transferred analogously to the method and vice versa.

FIG. 1 schematically shows a metal-ceramic substrate 1 according to the prior art. Such a metal-ceramic substrate 1 is preferably a carrier for electrical components. In particular, it is provided that the metal-ceramic substrate 1 has a ceramic element 30 and a component metallization 10, wherein the ceramic element 30 and the component metallization 10 extend along a main extension plane HSE. The component metallization 10 is bonded to the ceramic element 30, wherein the component metallization 10 and the ceramic element 30 are arranged on top of one another in a stacking direction S perpendicular to the main extension plane HSE. In particular, it is provided that the component metallization 10 has a plurality of metal sections, for example a first metal section 11, a second metal section 12 and a second third metal section 13, which are arranged, for example, electrically insulated from one another and next to one another along a direction running parallel to the main extension plane HSE.

In particular, it is common in the prior art to first bond the component metallization 10 to the ceramic element 30, in particular by means of a direct metal bonding process and/or an active soldering process or AMB process and/or an ADB process and/or hot isostatic pressing. Such bonding processes are high-temperature processes in which the arrangement of ceramic element 30 and component metallization 10 are exposed to an elevated temperature, in particular temperatures above 500° C. After the bonding process, structuring is then carried out, for example by means of an etching process, in order to realize electrically insulated metal sections, in particular a first metal section 11 and a second metal section 12, which can be used as conductor paths and/or connecting areas, so-called pads, for electrical circuits.

On the side of the ceramic element 30 opposite the component metallization 10, a backside metallization 20 is preferably bonded, which in particular is bonded to the ceramic element 30 at the same time, i.e. in a common work step, as the component metallization 10. Alternatively, the component metallization 10 and the backside metallization are bonded one after the other. Such a backside metallization 20 serves in particular to compensate for thermomechanical stresses in the metal-ceramic substrate 1, which are caused by the different thermomechanical expansion coefficients of the component metallization 10 and the ceramic element 30.

In this context, it is provided that the component metallization 10 has at least a first metal section 11, a second metal section 12 and/or a third metal section 13. After structuring, the first metal section 11, the second metal section 12 and/or the third metal section 23 are separated from one another by isolation sections 15 in order to form corresponding conductor paths and/or connecting areas that are electrically insulated from one another. For this purpose, structuring is embedded in the component metallization 10, for example by a chemical method and/or a mechanical method and/or an optical method, wherein a recess in the component metallization 10 necessary for the structuring extends at least as far as the ceramic element 30 in order to provide the necessary electrical insulation. Such isolation sections 15 are formed in particular in the form of trenches in the component metallization 10 and are also known colloquially as isolation trenches. The corresponding first courses VE1 of the trench-shaped isolation sections 15 follow a certain pattern depending on the application of the metal-ceramic substrate 1 provided as a printed circuit board. In particular, it is provided that the first course of the isolation sections 15 for a series of manufactured metal-ceramic substrates 1 is individually set for the corresponding application.

In order to provide the desired symmetry between a component side BS and a backside RS of the metal-ceramic substrate 1, thus allowing corresponding themomechanical stresses that occur in the metal-ceramic substrate 1 to compensate for each other, it is provided that the backside metallization 20 and the component metallization 10 have essentially a comparable thickness. The thicknesses are measured along a direction following the stacking direction S.

FIG. 2 shows a metal-ceramic substrate 1 according to a first exemplary embodiment of the present invention. In order to reduce the susceptibility of the metal-ceramic substrate 1 to deflection, it is provided here that, in addition to the isolation sections 15 in the component metallization 10, material weakenings 25 are embedded in the backside metallization 20. In the embodiment shown in FIG. 2, the material weakenings 25 are recesses in the backside metallization 20, which in particular extend as far as the ceramic element 20 and lead to complete insulation of partial sections of the backside metallization 30. In particular, it is provided that the material weakening 25 is arranged essentially congruently with the isolation section 15 as viewed in the stacking direction S. This advantageously further increases the symmetry between component side BS and backside RD and thus furthe reduces the susceptibility of the metal-ceramic substrate 1 to bending. It is furthe provided that the component metallization 10 has a first thickness D1 and the backside metallization 20 has a second thickness D2, wherein the first thickness D1 and the second thickness D2 are substantially equal. In this context, “substantially” is understood to mean that deviations between the first thickness D1 and second thickness D2 are less than 10%, more preferably less than 5% and most preferably less than 2.5% of the mean value of the first thickness D1 and/or second thickness D2.

Furthermore, it is provided that the ceramic element 30 has a third thickness D3. Preferably, it is provided that the third thickness D3 has a value which is less than 700 μm, more preferably less than 400 μm and most preferably less than 330 μm. These are thus comparatively thin insulating layers or ceramic elements 30, which are correspondingly more susceptible to bending. By increasing the symmetry, caused by the additional inclusion of the congruently arranged material weakening 25, it is thus also advantageously possible to counteract bending in such metal-ceramic substrates 1 in which a comparatively thin insulating layer, i.e. a comparatively thin ceramic element 30, is used.

Furthermore, it is provided that the isolation section has a first width B1 and the material weakening 25 has a second width B2. Preferably, it is provided that the second width B2 is smaller than the first width B1. In particular, it is conceivable that a ratio of the second width B2 to the first width B1 has a value of between 0.1 and 2.0, more preferably between 0.5 and 1.5 and most preferably between 0.75 and 0.5. In the embodiment example shown in FIG. 2, the side surfaces of the backside metallization 20 in the area of the material weakening 25 formed as a recess run essentially perpendicular to the main extension plane HSE. Preferably, however, it is provided here that the formed side surfaces are curved or inclined, in particular if the material weakening 25 embedded in the backside metallization 20 is realized by an etching process.

The first width of the isolation section 15 is determined in particular by the minimum distance between two opposing metal sections 11, 12, 13 at the point of the isolation section 15 that is to be measured. A first direction R1, along which the first width B1 is determined, lies within the main extension plane HSE and in particular perpendicular to the direction along which the isolation section 15 extends according to a first course VE1 in the main extension plane HSE. This first course VE1 is predetermined by the corresponding pattern provided for the respective metal-ceramic substrate 1. The size of the second width B2 is preferably determined at the same position on the backside RS along the same first direction R1.

Furthermore, “congruent” is to be understood as meaning that along an imaginary projection of the extension of the material weakening 25 onto the extension of the isolation section 15, which is parallel to the stacking direction S, a spatial overlap could be determined, which is in particular greater than 50%, preferably greater than 75% and more preferably greater than 95%. The centers of the extensions of the material weakening 25 and the center of the isolation section 15 can lie on top of each other in the stacking direction or be offset laterally with respect to each other, in particular in the main extension plane HSE along a direction running perpendicular to the first course VE1 or perpendicular to the second course VE2.

FIG. 3 shows a sectional view through a metal-ceramic substrate 1 according to a second exemplary embodiment of the present invention. The embodiment example of FIG. 3 essentially differs from the embodiment example of FIG. 2 only in that in the embodiment example of FIG. 3, the material weakening 25 formed as a recess does not extend as far as the ceramic element 30. In particular, it is provided here that a residual metallization 40 is provided in the area of the material weakening 25. This residual metallization 40 has a fourth thickness D4, which is smaller than the second thickness D2. Preferably, a ratio of the fourth thickness D4 to the second thickness D2 is less than 0.5, more preferably less than 0.25 and most preferably less than 0.1. This embodiment example has the advantage that the residual metallization 40 can be used to contribute to the stability of the ceramic element 30, wherein at the same time the idea of symmetry of the component side BS and the backside RS is taken into account. It is conceivable that the second thickness D2 is smaller than the first thickness D1 in order to compensate for the presence of the residual metallization 40. Furthermore, it is conceivable that in a further embodiment example, material weakening 25 provided as a recess in a metal-ceramic substrate 1 partially extend to the ceramic portion 30 and other sections have residual metallization 40. In other words, the metal-ceramic substrate 1 comprises material weakenings 25 formed as recesses, some of which extend as far as the ceramic element 30 and some of which have a residual metallization 40.

Furthermore, it is conceivable that in another embodiment example, the fourth thickness D4 is different for different material weakenings 25 and varies and in particular is adapted to the extent of the expected thermomechanical stresses for the respective layout/pattern or for the respective planned first courses VE1 of the isolation sections 15.

FIG. 4 shows a side view (center), a top view of the backside RS (top) and a top view of the component side BS (bottom) of a metal-ceramic substrate 1 according to a third exemplary embodiment of the present invention). In particular, it is provided that the material weakening 25 in the backside metallization 20 is formed as a row of holes or as a succession of material weakenings 25. Such a row of holes proves to be advantageous in particular because the metallization retained between the individual holes increases the stability of the metal-ceramic substrate 1 while at the same time increasing the symmetry of the material recesses on component side BS and backside RS of the metal-ceramic substrate 1. Preferably, the row of holes is a series of circular and/or dome-shaped recesses. The embodiments of the recess shown in the sectional view extend once to the ceramic element 30 (left) and once the recess ends in the backside metallization (right), i.e. a residual metallization 40 is provided between the recess and the ceramic element 30.

Furthermore, it is provided that the row of holes or the sequence of material weakening 25 follows a second course VE2, which in particular is congruent with a first course VE1, which is provided by the isolation section 15 on the component side BS or in the component metallization 10. The first course VE1 and the second course VE2 in the main extension plane HSE may each have subsections that are angled relative to one another and/or have curved subsections that, for example, join straight subsections together. It is also conceivable that the first course VE1 and/or second course VE2 have branches.

Furthermore, it is preferably provided that a first distance AB1 between two adjacent recesses or material weakenings 25 is smaller than 600 μm, more preferably smaller than 400 μm and most preferably smaller than 250 μm. In particular, it is provided that the first distance AB1 between two material weakenings is greater than the first extension E1.

It is also conceivable that the recesses arranged as a row of holes touch each other or merge into each other and are not separated from each other by a metal section that extends to the outer side of the backside metallization.

Furthermore, it is more preferably provided that, in addition to the material weakening 25, a further material weakening 26 is provided, which is formed in the peripheral region of the backside metallization 20. In particular, the further material weakening 26 is formed as a series of further material weakenings 26, in particular as a row of holes, wherein the series extends in a frame-like manner along a peripheral region of the backside metallization 20 or the metal-ceramic substrate 1.

In particular, it is provided that the course of the further material weakening 26 lies outside an area in which the material weakenings 25 are formed, which are arranged congruently with the first course VE1 or the arrangement of the isolation sections 15 on the component side BS. Furthermore, it is provided that the further material weakening 26, in particular formed as further recesses, has a first expansion E1 on the outer side of the backside metallization 20, which faces away from the ceramic element 30, which is smaller than the first extension E1 of the material weakening 25. Furthermore, a ratio of the first extension E1 of the further material weakening 26 to the first extension E1 of the material weakening 25 has a value that is less than 0.7, less than 0.6 and most preferably less than 0.5. Preferably, the first extension E1 of the further material weakening 26 is less than 1.2 mm, more preferably less than 0.9 mm and most preferably less than 0.7 mm. Furthermore, it is more preferably provided that a first distance AB1 between two adjacent further material weakenings 26 is smaller than the distance between two material weakenings 25. The distance between the material weakenings 25 or further material weakenings 26 is determined here from center to center of the respective recess. Furthermore, it is preferably provided that the peripheral region is understood to be that region which extends from the outer circumference in the direction of the center of the backside metallization 20, wherein the extent of the peripheral region is limited to a maximum of 10% of the total extent of the backside metallization 20, in particular a maximum of 5% and more preferably a maximum of 2%.

FIG. 5 shows sectional views through two different forms of material weakening 25. In particular, it is provided that the dome-shaped recess has a first extension E1 on an outer side of the backside metallization 20 facing away from the ceramic element 30. Preferably, it is provided that the first extension E1 is essentially identical for all material weakenings 25, in particular all dome-shaped recesses. It is also conceivable that the size of the first extension E1 for the different dome-shaped recesses, which are arranged congruently with the isolation sections 15, differ from one another.

Preferably, it is provided that a first extension E1 of the material weakening 25, in particular of the dome-shaped recess, is smaller than 1.5 mm, more preferably smaller than 1.0 mm and most preferably smaller than 0.75 mm. If the dome-shaped recess extends as far as the ceramic element 30, it is preferably provided that a second extension E2 of the material weakening 25 on the outer side of the backside metallization 20 facing the ceramic element 30 is smaller than 1.3 mm, more preferably smaller than 0.8 mm and most preferably smaller than 0.6 mm. In particular, a ratio of the second extension E2 to the first extension E1 has a value between 0.6 and 0.95, more preferably between 0.7 and 0.9 and most preferably between 0.75 and 0.85.

FIG. 6 shows a component metallization 10 (bottom) and a backside metallization 20 (top) as well as a side view (middle) for a metal-ceramic substrate 1 according to a fourth exemplary embodiment. The embodiment of FIG. 6 differs from that of FIG. 4 in particular in that the first course VE1 and the second course VE2, which are congruent with one another and are each arranged in a central region of the component metallization 10 or the backside metallization 20, have several subsections that are angled towards one another. This is necessary in order to realize the desired pattern for forming conductor paths or connection pads. In particular, the figure below shows a first course VE1 along which the isolation section 15 extends in the plane running parallel to the main extension plane HSE. In the top view selected here, it can be seen that the ceramic element 30 protrudes in a direction parallel to the main extension plane HSE with respect to the component metallization 10 in order to form a pullback.

Essentially, in the embodiment example of FIG. 6, it is provided that the backside metallization 20 provides material weakening 25, which are arranged congruently with the first course VE1 of the isolation section 15 on the component metallization 10 and further material weakenings 26, which are arranged in the peripheral region of the backside metallization 20. It can be seen that the further material weakenings 26 in the peripheral region are not arranged congruently with the entire isolation section 15.

In the embodiment of FIG. 6, it is further provided that the ceramic element 30 protrudes less with respect to the backside metallization 20 in a direction running parallel to the main extension plane HSE than with respect to the component metallization 10. This reduces the probability of flashover on the component side BS with the increased distance to the end of the ceramic element 30, while on the backside RS, stabilization of the metal-ceramic substrate 1 is supported by the peripheral region of the backside metallization 20. In particular, it is provided that the further material weakening 26 is arranged in the peripheral region of the backside metallization 20 in the region of the backside metallization 20 that protrudes in a direction parallel to the main extension plane HSE with respect to the component metallization 10. In the side view, it can be seen that the backside metallization 20 is larger in its extension in the main extension plane HSE than the component metallization 10 and protrudes in a direction parallel to the main extension plane HSE with respect to the component metallization 10.

Furthermore, it is conceivable (not shown) that the second course VE2 of the material weakenings 25 is arranged completely congruent with the isolation section 15, but the second course VE2 comprises partial sections in which a material weakening 25 is omitted. Thus, the first course VE1 is not completely congruent with the second course VE2, since there are subregions of the first course VE1 for which no material weakening 25 is provided on the backside metallization 20. This is particularly useful for those areas in which a high density of isolation trenches or isolation sections 15 is provided, whereby the introduction of corresponding material weakenings 25 on the backside RS would lead to a corresponding destabilization of the metal-ceramic substrate 1.

FIG. 7 schematically shows a comparison between a recess assigned to the isolation section 15 and a recess assigned to a material weakening 25 for a metal-ceramic substrate 1. In other words: in the central area of FIG. 7, top views of the component side BS and of the backside RS are shown in each case, thus revealing a first surface A1 for the recess of the isolation section 15, as well as several material weakenings 25 in the form of dome-shaped recesses, which in the top view of the backside RS form a series of, for example, second surfaces A2 of the same size in total.

A sectional view through the component metallization (top) and the backside metallization (bottom) is also shown along the sectional line AA, which is also inserted here. The recess, which is assigned to the isolation section 15 on the component side BS, has a first depth T1, while the material weakening 25 formed as a dome-shaped recess has a second depth T2. In order to achieve the greatest possible symmetry, it is provided that, for a fixed unit of length LE, a first volume V1 of the one or more recesses for forming the isolation section 15 corresponds in size to a second volume V2 which the recess or the several recesses in the backside metallization 10 occupy per unit of length LE in an area in the backside metallization 20 opposite the isolation section 15. The unit of length LE is preferably formed by the first distance AB1 between two adjacent material weakenings 25 and/or extends across 1 cm, more preferably 2 cm and most preferably 2.5 cm. In particular, it is provided that despite the same size of the volumes, the shapes of the first volume V1 and the second volume V2 are different. For example, the isolation section 15 is formed by a continuous recess, while the material weakenings 25 on the backside RS are formed on dome-shaped recesses. As a result, for example, the second depth T2 does not correspond to the first depth T1 and the length of the recess, measured along the first course VE1 and/or second course VE2, which is associated with the isolation section 15 does not correspond to the corresponding length of the material weakening 25. If the recess in the material weakening 25 extends to the ceramic element 30, it is more preferably provided that, for example, a first area A1 per unit of length LE corresponds approximately to the summed second area A2 in the backside RS due to an increased diameter for the recess in the backside RS. In order to take account of the different forms of material weakening 25 in relation to the recess for forming the isolation section 15, a diameter, i.e. a second width B2, of a dome-shaped recess can, for example, be selected to be larger than a corresponding first width B1 of the associated isolation section 15. This proves to be advantageous in particular because more material is thus retained on the backside RS, thus increasing the stability of the entire metal-ceramic substrate 1, in particular in the area of the isolation section 15. At the same time, however, it is avoided that the symmetry is reduced, which in turn could cause the metal-ceramic substrate 1 to bend, particularly during operation.

In addition, it is possible to set the first volume V1 and/or second volume V2 by a corresponding first depth T1 and/or second depth T2 in such a way that the first volume V1 and the second volume V2 essentially correspond to each other.

In this context, the person skilled in the art understands “substantially” to mean that deviations of less than 10%, more preferably of less than 5% and most preferably of less than 2.5% of the relevant quantity or of the mean value of the values to be compared are to be expected.

### REFERENCE NUMBERS

1 Metal-ceramic substrate
10 component metallization
11 First metal section
12 second metal section
13 Third metal section
15 Isolation section
20 Backside metallization
25 Material weakening
26 Further material weakening
30 Ceramic element
40 Residual metallization
S Stacking direction
BS component side
RS Backside
HSE main extension plane
R1 first direction
B1 first width
B2 second width
D1 first thickness
D2 second thickness
D3 third thickness
D4 fourth thickness
V1 first volume
V2 second volume
VE1 first course
VE2 second course
AB1 first distance
T1 first depth
T2 second depth
E1 first extension
E2 second extension

1-11. (canceled)

12. A metal-ceramic substrate (1) provided as a printed circuit board for attaching electrical components, comprising
a component metallization (10) and a backside metallization (20), and
a ceramic element (30) arranged along a stacking direction(S) between the component metallization (10) and the backside metallization (20),
wherein the component metallization (10) comprises a first metal section (11) and a second metal section (12), wherein the first metal section (11) and the second metal section (12) are separated from each other by an isolation section (15), and
wherein the backside metallization (20) has a material weakening (25), which, viewed in the stacking direction(S), is arranged at least partially congruently with the isolation section (15), characterized in that a plurality of separated material weakenings (25) is formed, wherein two adjacent material weakenings (25) are arranged at a first distance from one another, which is less than 600 μm and a first total area in the component metallization occupied by the isolation sections is greater than a second total area in the backside metallization occupied by the material weakening, wherein a ratio of the second total area to the first total area has a value which is between 0.6 and 0.9.

13. The metal-ceramic substrate (1) according to claim 12, wherein the material weakening (25) is formed as a dome-shaped recess.

14. The metal-ceramic substrate (1) according to claim 12, wherein the isolation section (15) in the component metallization (10) follows a first course (VE1) in a plane extending parallel to the main extension plane (HSE) and the material weakening (25) or several material weakenings (25) in the backside metallization (20) follow a second course (VE2) in a plane extending parallel to the main extension plane (HSE).

15. The metal-ceramic substrate (1) according to claim 14, wherein the second course (VE2) of the material weakening (25) or the material weakenings (25) is formed by a series of material weakenings (25), and/or has a stabilization region along the second course (VE2) between two material weakenings (25).

16. The metal-ceramic substrate (1) according to claim 12, wherein a further material weakening (26) is provided, which is embedded in the backside metallization (20) in a peripheral region of the backside metallization (20).

17. The metal-ceramic substrate (1) according to claim 12, wherein the material weakening (25) formed as a recess in the backside metallization (20) extends to the ceramic element (30).

18. The metal-ceramic substrate (1) according to claim 16, wherein a residual metallization (40) is formed between the further material weakening (26) formed as a recess and the ceramic element (30).

19. The metal-ceramic substrate (1) according to claim 14, wherein a ratio of sections wherein the first course (VE1) and the second course (VE2) do not run congruently with one another when viewed in the stacking direction(S), to sections wherein the first course (VE1) and the second course (VE2) run congruently with one another when viewed in the stacking direction(S), has a value which is less than 1.

20. The metal-ceramic substrate (1) according to claim 14, wherein per unit of length (LE) along the first course (VE1) and/or second course (VE2) the isolation section (15) has a first volume (V1) and the material weakening (25) or the material weakenings in the backside metallization (20) have a second volume (V2), wherein the first volume (V1) and the second volume (V2) are substantially equal with respect to their absolute size and are different with respect to their geometric shapes.

21. The metal-ceramic substrate (1) according to claim 12, wherein the material weakening (25) comprises a material recess.

22. The metal-ceramic substrate (1) according to claim 12, wherein the second course (VE2) is arranged congruently with the first course (VE1) in the stacking direction(S).

23. The metal-ceramic substrate (1) according to claim 15, wherein the series of material weakenings (25) is in the form of a row of holes.

24. The metal-ceramic substrate (1) according to claim 16, wherein the further material weakening (26) is embedded in the component metallization (10) independently of an isolation section (15).

25. The metal-ceramic substrate (1) according to claim 19, wherein the ratio has a value which is less than 0.5.

26. The metal-ceramic substrate (1) according to claim 19, wherein the ratio has a value which is less than 0.2.

27. A method of manufacturing a metal-ceramic substrate (1) according to claim 12, ponent metallization (10) and a backside metallization (30) and a ceramic element (20),
bonding the component metallization (10) and the backside metallization (30) to the ceramic element (20), wherein the ceramic element (20) is arranged along a stacking direction(S) between the component metallization (10) and the backside metallization (20),
structuring the component metallization (10) by realizing isolation sections (15) and
realizing a material weakening (25) in the backside metallization (20), wherein the material weakening (25) is arranged congruently with the isolation section (15) and/or a connection region of the first metal section as viewed in the stacking direction(S).

28. A metal-ceramic substrate (1) provided as a printed circuit board for attaching electrical components, comprising
a component metallization (10) and a backside metallization (20), and
a ceramic element (30) arranged along a stacking direction(S) between the component metallization (10) and the backside metallization (20),
wherein the component metallization (10) has a first metal section (11) and a second metal section (12), wherein the first metal section (11) and the second metal section (12) are separated from each other by an isolation section (15) and/or a connection region for an electrical component is provided on the first metal section, and
wherein the backside metallization (20) has a material weakening (25) in the form of a material recess which, viewed in the stacking direction(S), is arranged at least partially congruent with the connection region, characterized in that a plurality of separated material weakenings (25) is formed, wherein the backside metallization has both material recesses which are congruent with the isolation sections and material recesses which are congruent with the connection region.
